(19) United States
(12) Patent Application Publication
(10) Pub. No.: US 2026/0328815 A1
(43) Pub. Date: Oct. 22, 2026

(54) CURRENT-MEASURING DEVICE FOR AN ELECTRIC MACHINE

(71) Applicant: INNOMOTICS GMBH, 90441 Nümberg (DE)

(72) Inventors: Matthias Centner, Dresden (DE); ENRICO TEICHERT, Cottbus (DE)

(73) Assignee: INNOMOTICS GMBH, 90441 Nümberg (DE)

(21) Appl. No.: 19/114,709

(22) PCT Filed: Sep. 27, 2023
(86) PCT No.: PCT/EP2023/076738

§ 371 Date: Mar. 24, 2025

(30) Foreign Application Priority Data
Sep. 30, 2022 (EP) 22199196.1

(51) Int. Cl. G01R 15/20; G01R 19/00

(52) U.S. Cl. CPC G01R 15/202; G01R 19/0092

(57) ABSTRACT

A current-measuring facility for an electric machine includes a sensor which is arranged in a region of homogenous magnetic field lines, a first flux-conducting element, a second flux-conducting element, a first distancing element and a second distancing element. The first distancing element is designed to distance the first flux-conducting element from the second flux-conducting element.

The invention relates to a current-measuring facility of an electric machine or a method for current measurement for an electric machine.

It is possible in the case of an electric machine to measure its operating parameters or test parameters. Examples of such parameters are a current or a voltage. Such measurement values, I.e. an actual current or an actual voltage, can be used for the closed-loop control, open-loop control and/or monitoring of the electric machine. It is also possible to refer to the monitoring of the electric machine as condition monitoring. The electric machine is, by way of example, a motor or a generator. The electric machine can be a synchronous machine or an asynchronous machine. If such electric machines have a high output in the megawatt (MW) range, this accordingly also results in high electrical currents and electrical voltages. By way of example, for the purpose of condition monitoring and also for test field purposes, the current is measured at the rotor of synchronous machines and transmitted with the aid of slip ring transmitters or contactless telemetry systems. Since the exciter currents can assume orders of magnitude >1000 A, special measuring devices are required for measuring them and these measuring devices are to be as cost-effective as possible. In addition to the special problem of measuring current at the rotor, the problem also occurs for stator currents which are to be made accessible to a monitoring system. In the case of synchronous machines, it is possible to use shunts for measuring the exciter currents. These components are components which are large and very expensive to manufacture individually for a current range under consideration of >1000 A. It is possible to use current converters as an alternative to the shunt, but these are also large and expensive. Furthermore, rotating applications, such as in the case of a rotor of an electric machine, require a robust construction suited to centrifugal force.

In the case of DC current, it is not possible to use current converters or Rogowski coils since these are not suitable for DC currents. Special LEM current converters which can be used for DC currents are difficult to produce for the desired measurement range and likewise very expensive. In addition, measuring via shunts has the disadvantage of not being potential-free.

It is possible via potential-free current converters to measure the current for AC stator currents, since these operate with voltages of up to multiple kV. Current converters require a certain amount of installation space and are also relatively expensive components. It is also not usually possible, for example, to additionally link into existing protection or measuring circuits with a monitoring system. Extra converters then represent a not insignificant cost factor.

One object of the invention is to propose a simple current-measuring facility for an electric machine. A further object of the invention is to propose a simple method for current measurement for an electric machine.

The object is achieved according to claim 1 or according to claim 9. Embodiments are created, by way of example, according to at least one of the claims 2 to 8 and 10.

A current-measuring facility for an electric machine has a sensor. The sensor is in particular a Hall sensor, also called a Hall-effect sensor or a Hall current sensor or Hall sensor. Hall sensors measure magnetic fields and thus, indirectly, the current via Ampère's law. Nonetheless, Hall sensors are often also referred to as current sensors. Hall current sensors can be used for measuring DC and AC currents, wherein these lie in particular in the range between 1000 A and 10000 A. The current-measuring facility has a first flux-conducting element and a first distancing element. Thus, the current-measuring facility has at least one flux-conducting element and at least one distancing element. In the case of the current-measuring facility, the first distancing element distances end regions of the first flux-conducting element or the first distancing element distances the first flux-conducting element from a second flux-conducting element. In one embodiment of the current-measuring facility, the first distancing element therefore distances end regions of the first flux-conducting element. In a further embodiment of the current-measuring facility, the first distancing element therefore distances the first flux-conducting element from the second flux-conducting element.

It is possible to measure the current (of the electrical current) using a Hall-effect sensor (Hall sensor) for measuring a magnetic field that can be caused by a current-carrying conductor. The sensor is Integrated in particular in a chip. The sensor is therefore in particular an integrated component. The measurement is performed in particular in the chip plane. For this purpose, there are different sensors which can measure magnetic fields in one or more spatial axes. The sensor is to be arranged in the distancing element in an appropriate manner. The magnetic field passes through the sensor, wherein materials can also be purposefully used for conducting the magnetic field in close proximity to the chip.

By virtue of using a flux-conducting element and a distancing element, practically almost any high currents can be measured with a chip. It is therefore possible to use a chip with a limited magnetic field measurement range.

In one embodiment of the current-measuring facility, the construction is based on the fact that the magnetic field surrounding the current-carrying conductor is measured. Since the Hall sensor has a specific field direction and maximally evaluable field strength, the construction can be configured in such a manner that the field strength can be easily adjusted and secondly, a relatively homogeneous field course is present in the range of the sensor in order to be in particular tolerance-insensitive, In one embodiment of the current-measuring facility, its construction is potential-free and includes, in particular, digital signal processing, which renders it possible to transmit the sensor signal with little interference or Interference-free over longer distances.

In one embodiment of the current-measuring facility, at least one flux-conducting element together with at least one distancing element surrounds a current conductor. In so doing, it can also create at least one air gap. This arrangement renders it possible to guide the magnetic field of a current-carrying electrical conductor.

In one embodiment of the current-measuring facility, at least one flux-conducting element and/or at least one distancing element can be exchanged.

In one embodiment of the current-measuring facility, it is adapted to different currents or field strengths by virtue of its variable use, i.e. an exchange, of one or more distancing elements and/or of one or more flux-conducting elements Distancing elements can be regarded as variable intermediate pieces between flux-conducting elements. The flux-conducting elements can be realized, by way of example, by an electrical sheet or by multiple electrical sheets layered one above the other. This creates a guide plate construction.

In one embodiment of the current-measuring facility, flux-conducting elements comprise a material with a particularly narrow hysteresis loop, such as for example a mu-metal. It is thus possible to influence the achievable measurement accuracy (in particular an advantageous improvement of the measurement accuracy).

In one embodiment of the current-measuring facility, the flux-conducting element or the flux-conducting elements in particular in a region which surrounds an electrical conductor are geometrically designed in such a manner that their geometric shape follows the magnetic field lines around the electrical conductor. In other words, the field ultimately follows the magnetic conductor.

In one embodiment of the current-measuring facility, a sensor carrier with the sensor is used in the case of geometrically different flux-conducting elements and/or in the case of a geometrically different distancing element, which are to be exchanged. The sensor carrier is, by way of example, an electronic printed circuit board or a carrier for an electronic circuit board on which the sensor is located.

In one embodiment of the current-measuring facility, this has at least one connecting element which connects the distancing element to the flux-conducting element, wherein the connecting element has in particular a non-magnetic material. The connecting element is, by way of example, a tensioning facility, a cable tie, a screw etc. It is possible to use, for example, copper or a synthetic material as the material.

In one embodiment of the current-measuring facility, the sensor is arranged in a distancing region. The sensor and/or the sensor carrier can thus be held, by way of example, by a distancing element or positioned therein.

In one embodiment of the current-measuring facility, the sensor is arranged in a region of homogeneous magnetic field lines. This renders it possible to achieve improved measurement accuracy.

In one embodiment of the current-measuring facility, the sensor is arranged at a minimum distance from a conductor (electrical conductor). As a result, the sensor can be better positioned in a region in which the magnetic field runs in a homogeneous manner.

In one embodiment of the current-measuring facility, at least one flux-conducting element is made of sheet metal. This renders it possible to reduce eddy currents or eddy current losses.

In one embodiment of the current-measuring facility, this has a radio facility for the wireless transmission of the measurement signals that are recorded by the sensor.

In the case of one method for measuring a current of an electric machine, a current-measuring facility according to one of the described embodiments is used.

In one embodiment of the method, a rotor current or a stator current of an electric machine is measured. The variability of the current-measuring facility renders it possible to use the same sensor in the case of different electric machines with different outputs.

In one embodiment of the method, at least one distancing element is exchanged for measuring different currents, in particular different maximum currents. It is thus possible to use a current-measuring facility in a flexible manner.

The variability of the current-measuring facility renders it possible to keep costs comparatively low in comparison to a shunt. Furthermore, this can create a comparatively very compact construction. A further advantage of the current-measuring facility can be achieved by a non-intrusive type of installation (the electrical circuit does not need to be opened). A further advantage of the current-measuring facility can be achieved by virtue of its possible potential-free construction. It can be important to be free of potential particularly at high currents or voltages. The costs are very low, the construction flexible and robust by virtue of a possible use of an integrated Hall sensor in combination with a microcontroller (in particular an Inexpensive microcontroller) and/or simple components (for example: metal sheets for flux-conducting elements, 3D-printed synthetic material structures for distancing elements or brass screws).

In one embodiment of the current-measuring facility or of the method, opportunities for making savings in comparison to the hitherto used shunt and further savings potentials arise if the sensor is also used for current-measuring in other fields (for example condition-monitoring systems etc.)

The features of the individual claimed or described embodiments can be readily combined with one another. The invention is further described and explained below with reference to figures. Identical reference characters refer to similar elements in the different figures. The features illustrated in the figures can be combined by persons skilled in the art to create new embodiments without departing from the invention. In the drawings:

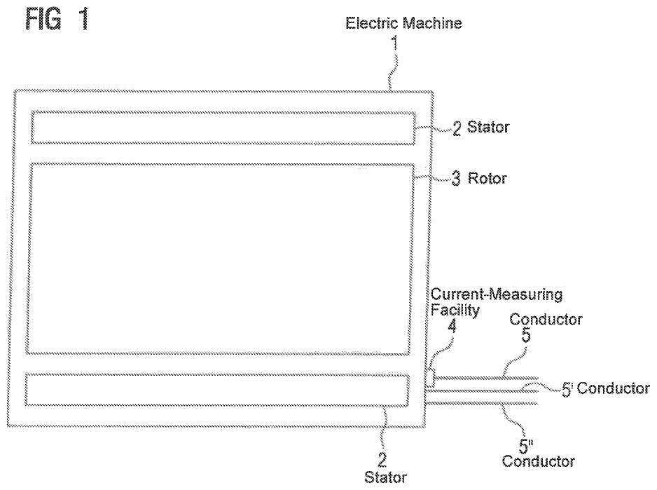

FIG. 1 shows an electric machine,

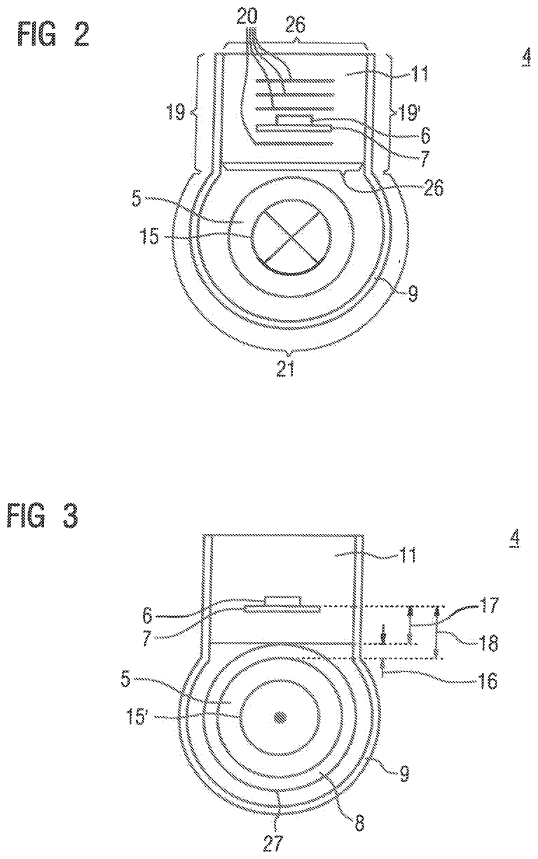

FIG. 2 shows a current-measuring facility, and

FIG. 3 to FIG. 8 show further current-measuring facilities.

The Illustration according to FIG. 1 shows an electric machine 1 with a stator 2 and a rotor 3. The electric machine 1 has an electrical connection to electrical current conductors (conductors) 5, 5′, 5″. A current-measuring facility 4 is provided for measuring an electrical current (current) in the conductor 5.

The Illustration according to FIG. 2 shows a current-measuring facility 4 for an electrical current conductor (electrical conductor) 5. The electrical conductor 5 in FIG. 2 has a round cross-section. A current flow through the electrical conductor 5 is represented by a symbol 15. This symbol 15 has a circle and a cross located in this circle. The current measuring facility 4 has a first flux-conducting element 9 which has end regions 19, 19′ and lying between them a magnetic conducting region 21. The magnetic conducting region 21 of the flux-conducting element 9 guides the magnetic field according to its course around a conductor. The end regions 19, 19′ are used to homogenize or to parallelize the magnetic field in a defined region. This region is a distancing region 26 which is created by a first distancing element 11. It is possible to form parallel-running magnetic field lines 20 in this region 26. A sensor 6 is positioned on a printed circuit board 7 in this region where the parallel-running magnetic field lines 20 can form themselves. The sensor 6 can be pushed or positioned, by way of example, together with the printed circuit board 7 into a recess of the distancing element 11.

The illustration according to FIG. 3 shows a current-measuring facility 4 for an electrical current conductor 5. The electrical conductor 5 in FIG. 3 also has a round cross-section. A current through-flow through the electrical conductor 5 is represented in FIG. 3 by a symbol 15′. This symbol 15′ has a circle and a dot located in this circle. In this context, the dot and the cross (see FIG. 1) face different flow directions. According to FIG. 3, the conductor 5 has an Insulation 8 with a thickness 16. The electrical conductor 5 and the insulation 8 create a cable 27, the cross-section of which is Illustrated. The distancing element 11 is directly adjacent to the insulation 8 of the conductor 5. The sensor 6 has a first distance 17 from the cable 27. The sensor 6 has a second distance 18 from the electric conductor 5. The distances 17, 18 are so great that the sensor 6 lies in a region which has parallel-running magnetic field lines. This is particularly important for different current strengths.

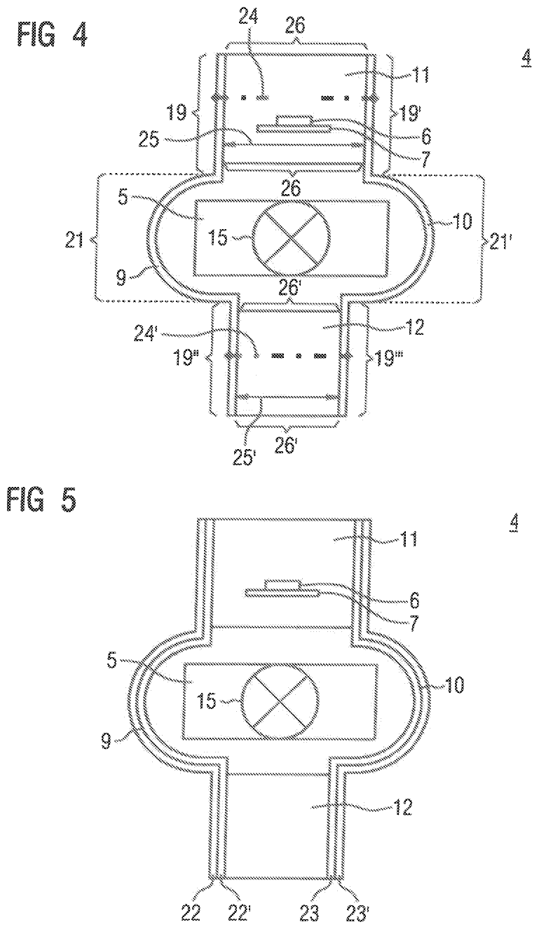

The illustration according to FIG. 4 shows a current-measuring facility 4 for an electrical current conductor (electrical conductor) 5. The electrical conductor 5 in FIG. 4 has a rectangular cross-section. A first flux-conducting element 9 and a second flux-conducting element 10 are also shown. The first flux-conducting element 9 has end regions 19 and 19″. The second flux-conducting element 10 has end regions 19′ and 19′″. The first flux-conducting element 9 is spaced from the second flux-conducting element 10 in the end regions 19 and 19′ by the first distancing element 11. The first flux-conducting element 9 is also spaced from the second flux-conducting element 10 in the end regions 19″ and 19′″ by the second distancing element 12. In the first distancing element 11, the sensor 6 is located on the printed circuit board 7. The first distancing element 11 creates a first distancing region 26 with a spacing 25 between the end regions 19 and 19′. The second distancing element 12 creates a second distancing region 26″ with a spacing 25′ between the end regions 19″ and 19′″. The first distancing element 11 is connected by a connecting element 24 to the first flux-conducting element 9 and to the second flux-conducting element 10 in the distancing region 26. The first distancing element 11 is connected by a connecting element 24′ to the first flux-conducting element 9 and to the second flux-conducting element 10 in the distancing region 26′. The flux-conducting elements 9, 10 have magnetic conducting regions 21, 21′, The respective flux-conducting element has a curved shape or circular shape in the conducting region.

The Illustration according to FIG. 5 shows a current-measuring facility 4 for an electrical current conductor 5. The flux-conducting elements 9, 10 are realized as sheet metal, wherein according to FIG. 5 in each case two metal sheets 22, 22′, 23, 23′ are shown per flux-conducting element 9, 10. This renders it possible to reduce eddy current losses.

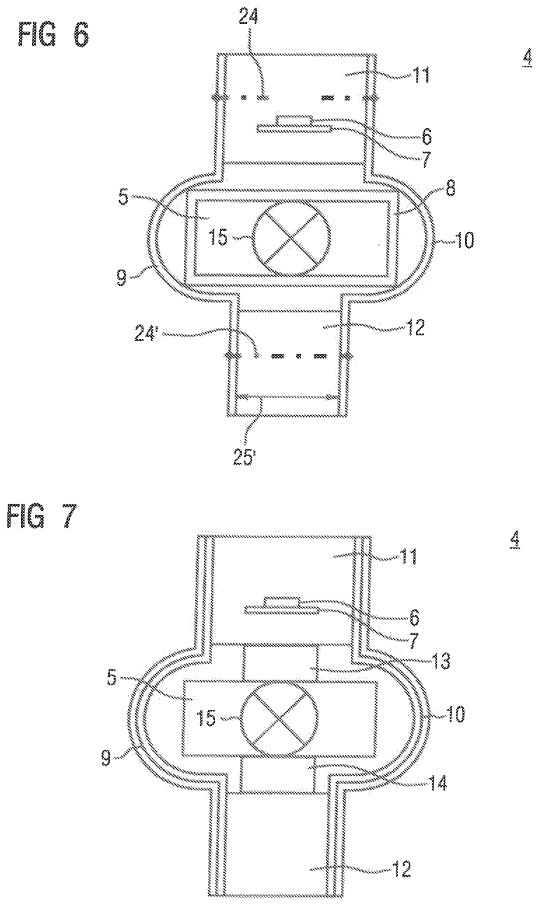

The illustration according to FIG. 6 shows a current-measuring facility 4 for an electrical current conductor 5. The electrical conductor 5 in FIG. 6 has a rectangular cross-section.

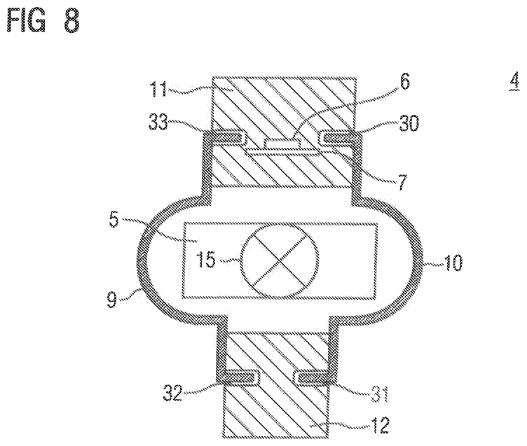

The Illustration according to FIG. 7 shows a current-measuring facility 4 for an electrical current conductor 5. The electrical conductor 5 in FIG. 7 is spaced from the distancing elements 11, 12 by spacer elements 13, 14. The current conductor 5 is positioned in the current-measuring facility 4 by virtue of a first spacer element 13 and a second spacer element 14, which are both Insulators.

The Illustration according to FIG. 8 shows a current-measuring facility 4 for an electrical current conductor 5. The distancing elements 12, 13 have notches 30, 31, 32 and 33, into which the flux-conducting elements 9, 10 protrude. The notches are adjacent to the position of sensor 6. The sensor 6 in FIG. 8 has a different geometry to the sensors 6 in FIGS. 2 to 7. This shows that sensors that have different geometries can be used. The mounting position of the sensor is to be selected or rotated in such a manner that it is possible to perform a successful measurement. Accordingly, by way of example, different sensors are to rotate (for example by 90 degrees) in order to achieve a suitable measurement. The sensor is to be oriented according to the magnetic field direction in the measurement environment and in the sensor.

1-10. (canceled)

11. A current-measuring facility for an electric machine, the current-measuring facility comprising:
a sensor arranged in a region of homogenous magnetic field lines;
a first flux-conducting element;
a second flux-conducting element;
a first distancing element designed to distance the first flux-conducting element from the second flux-conducting element; and
a second distancing element.

12. The current-measuring facility of claim 11, wherein the first flux-conducting element includes end regions and the second flux-conducting element includes further end regions, with the first flux-conducting element being distanced from the second flux-conducting element in the end regions by the first distancing element, and with the first flux-conducting element being distanced from the second flux-conducting element in the further end regions by the second distancing element.

13. The current-measuring facility of claim 11, further comprising a current conductor surrounded by the first and second flux-conducting elements together with the first and second distancing elements.

14. The current-measuring facility of claim 11, wherein at least one of the first and second flux-conducting elements and/or at least one of the first and second distancing elements is exchangeable.

15. The current-measuring facility of claim 11, further comprising a connecting element designed to connect one of the first and second distancing elements to the first and second flux-conducting elements.

16. The current-measuring facility of claim 15, wherein the connecting element includes a non-magnetic material.

17. The current-measuring facility of claim 11, wherein the sensor is arranged in a distancing region.

18. The current-measuring facility of claim 11, further comprising a current conductor, said sensor being arranged at a minimum distance from the current conductor.

19. The current-measuring facility of claim 11, wherein at least one of the first and second flux-conducting elements is realized as sheet metal.

20. The current-measuring facility of claim 11, wherein the sensor is received in a recess of the first distancing element.

21. A method for measuring a current of an electric machine, the method comprising:
arranging a sensor in a region of homogenous magnetic field lines;
distancing a first flux-conducting element from a second flux-conducting element by a first distancing element; and
providing a second distancing element.

22. The method of claim 21, further comprising designing at least one the first and second distancing elements exchangeable for measuring different currents.

23. The method of claim 21, wherein the first flux-conducting element is distanced from the second flux-conducting element in end regions of the first flux-conducting element by the first distancing element, and wherein the first flux-conducting element is distanced from the second flux-conducting element in further end regions of the second flux-conducting element by the second distancing element.

24. The method of claim 21, further comprising surrounding a current conductor by the first and second flux-conducting elements together with the first and second distancing elements.

25. The method of claim 21, further comprising connecting at least one of the first and second distancing elements to the first and second flux-conducting elements by a connecting element.

26. The method of claim 25, wherein the connecting element includes a non-magnetic material.

27. The method of claim 21, further comprising arranging the sensor in a distancing region.

28. The method of claim 21, further comprising arranging the sensor at a minimum distance from a current conductor.

29. The method of claim 21, further comprising realizing at least one of the first and second flux-conducting elements as sheet metal.
